(19) United States
(12) Patent Application Publication
(10) Pub. No.: US 2025/0279254 A1
(43) Pub. Date: Sep. 4, 2025

(54) Modular Pole Assembly for Overhead Line Systems

(71) Applicant: ABB Schweiz AG, Baden (CH)

(72) Inventors: S Chiplunkar, Nashik (IN); Chetan Dilip Patil, Nashik (IN); Bhalchandra Narayan Varade, Nashik (IN); Vikas Jakate, Nashik (IN); Shamim Malik, Nashik (IN); Pooja Trivedi, Vadodara (IN)

(73) Assignee: ABB Schweiz AG, Baden (CH)

(21) Appl. No.: 19/210,035

(22) Filed: May 16, 2025

Related U.S. Application Data
(63) Continuation of application No. PCT/IB2022/061022, filed on Nov. 16, 2022.

(51) Int. Cl. H01H 33/662; G01R 31/12; H02G 7/05

(52) U.S. Cl. CPC H01H 33/66207; G01R 31/1245; H02G 7/05; H01H 2033/66223; H01H 2033/6623

(57) ABSTRACT

A modular pole assembly for overhead line systems includes a top insulator housing defined by a first end and a second end. A bottom insulator housing is defined by a third end and a fourth end. The third end of the bottom insulator housing is removably coupled to the second end of the top insulator housing. A chamber is defined by at least one wall extending perpendicularly from at least one of the second end of the top insulator housing and the third end of the bottom insulator housing. The chamber is structured to accommodate at least one sensor.

### CROSS-REFERENCE TO RELATED APPLICATIONS

The instant application claims priority to International Patent Application No. PCT/IB2022/061022, filed Nov. 16, 2022, which is incorporated herein in its entirety by reference.

### FIELD OF THE DISCLOSURE

The present disclosure generally relates to a modular pole assembly and, more particularly, to a configuration of the modular pole assembly that is adaptable to an overhead line system.

### BACKGROUND OF THE INVENTION

Generally, a pole assembly consists of an interrupter along with current carrying components, which are either placed inside a housing or are molded together to form a pole assembly. The interrupter and the current carrying components are placed inside the housing and assembled with connecting parts. The vacuum interrupter may be operated by an actuator for selectively allowing or restricting the flow of current through the pole assembly.

Further, the pole assembly may be used in overhead line systems. The overhead line system may be circuit breakers, auto recloser or vacuum switch disconnectors. The overhead line system may include the pole assembly. The pole assembly may be of a live tank set up or of a dead tank set up. The pole assemblies may include insulating jackets that are molded to the outer surface in the liver tank pole assembly set up. Further, the dead tank set up may directly accommodate the pole assembly in a dead potential casing.

Conventionally, pole assemblies were individually or separately manufactured for live tank configuration and dead tank configuration. The pole assemblies also include a sensor for measuring the voltage across the pole assembly. The sensor in conventional pole assemblies is molded or integrated with the pole assembly. Consequently, any damage to the sensor resulted in complete replacement of the pole assembly. Therefore, the overall operational and maintenance costs are increased, which is undesired.

### BRIEF SUMMARY OF THE INVENTION

One or more shortcomings of conventional systems are overcome, and additional advantages are provided through an assembly as claimed in the present disclosure. Additional features and advantages are realized through the techniques of the present disclosure. Other embodiments and aspects of the disclosure are described in detail herein and are considered a part of the claimed disclosure.

In a non-limiting embodiment of the disclosure, a modular pole assembly for overhead line systems is disclosed. The modular pole assembly includes a top insulator housing defined by a first end and a second end. A bottom insulator housing is defined by a third end and a fourth end where the third end of the bottom insulator housing is removably coupled to the second end of the top insulator housing. A chamber is defined by at least one wall extending perpendicularly from at least one of the second end of the top insulator housing and the third end of the bottom insulator housing. Further, the chamber is structured to accommodate at least one sensor.

### BRIEF DESCRIPTION OF THE SEVERAL VIEWS OF THE DRAWING(S)

FIG. 1 is a perspective view of a modular pole assembly in a live tank configuration in accordance with an embodiment of the disclosure.

FIG. 2 is a sectional view of the modular pole assembly of FIG. 1.

FIG. 3 is an exploded view of the modular pole assembly, in accordance with an embodiment of the disclosure.

FIG. 4 is a magnified view of a portion of the modular pole assembly of FIG. 3.

FIG. 5 is a perspective view of a sensor of the modular pole assembly, in accordance with an embodiment of the disclosure.

FIG. 6 is a sectional view of the sensor of the modular pole assembly, in accordance with an embodiment of the disclosure.

FIG. 7 is a perspective view of a silicon jacket of the modular pole assembly, in accordance with an embodiment of the disclosure.

FIG. 8 is a sectional view of the silicon jacket of FIG. 7.

FIG. 9 is a perspective view of the modular pole assembly without the silicon jackets, in accordance with an embodiment of the disclosure.

FIG. 10 is a perspective view of the modular pole assembly in a dead tank configuration, in accordance with an embodiment of the disclosure.

### DETAILED DESCRIPTION OF THE INVENTION

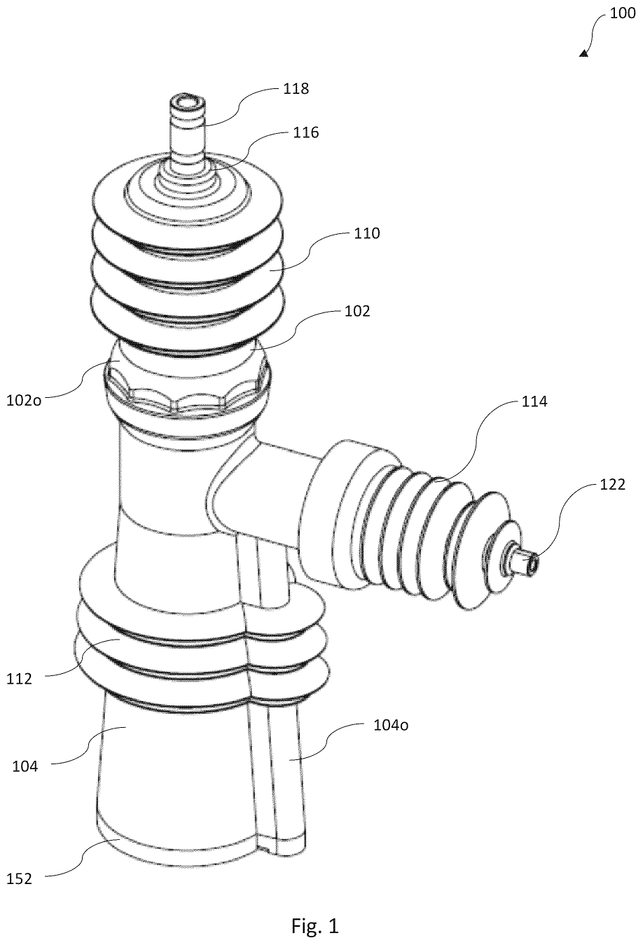

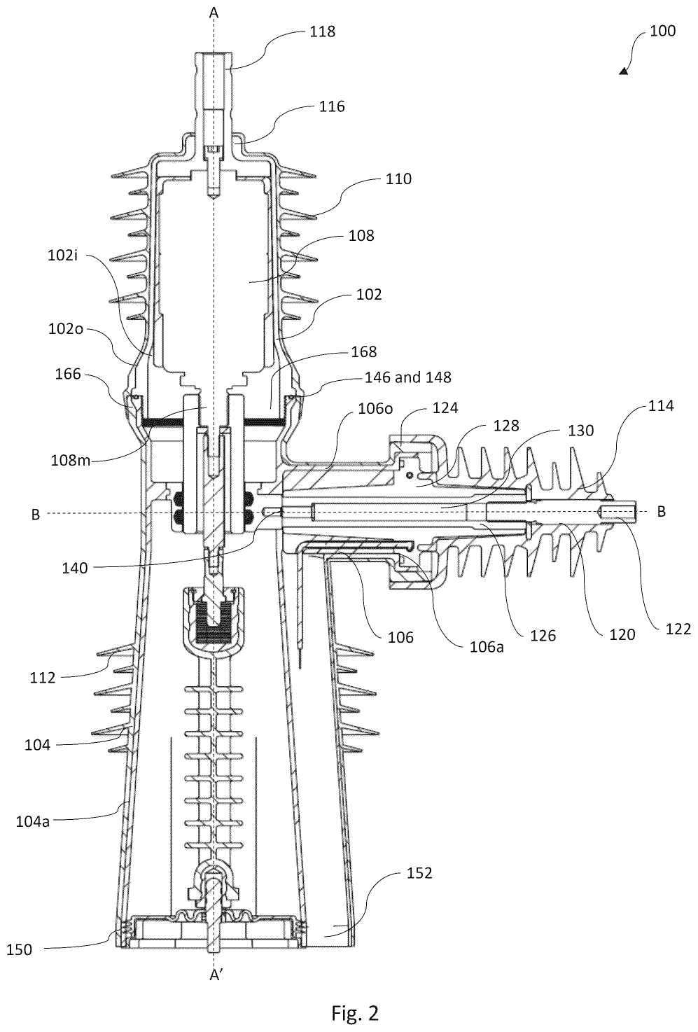

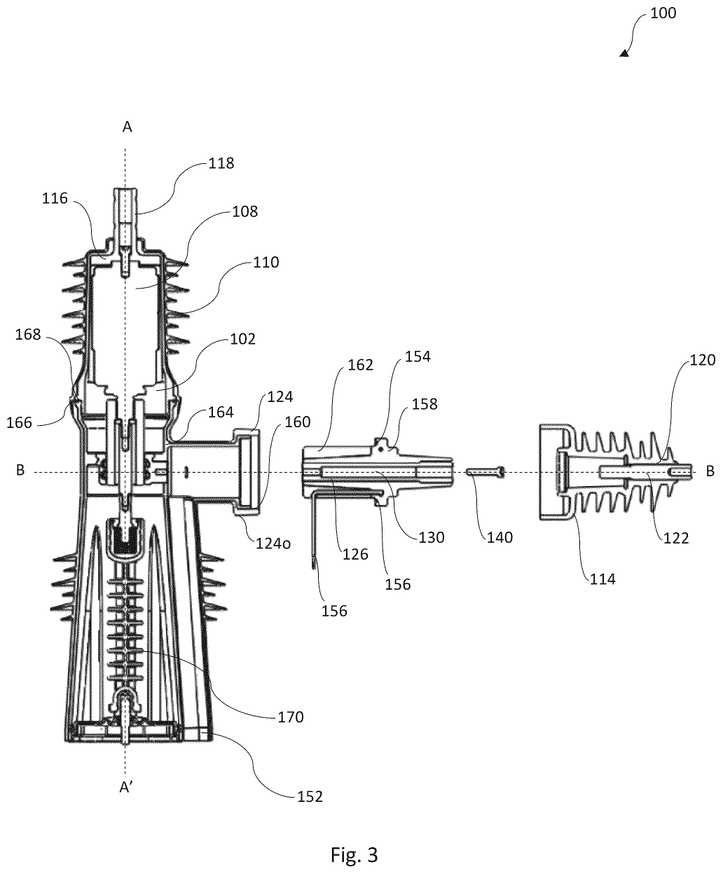

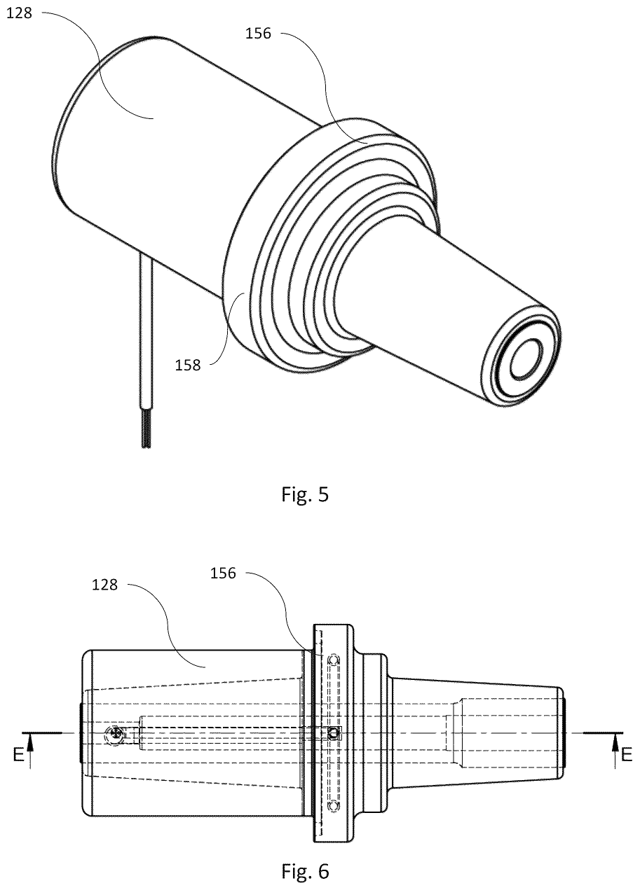

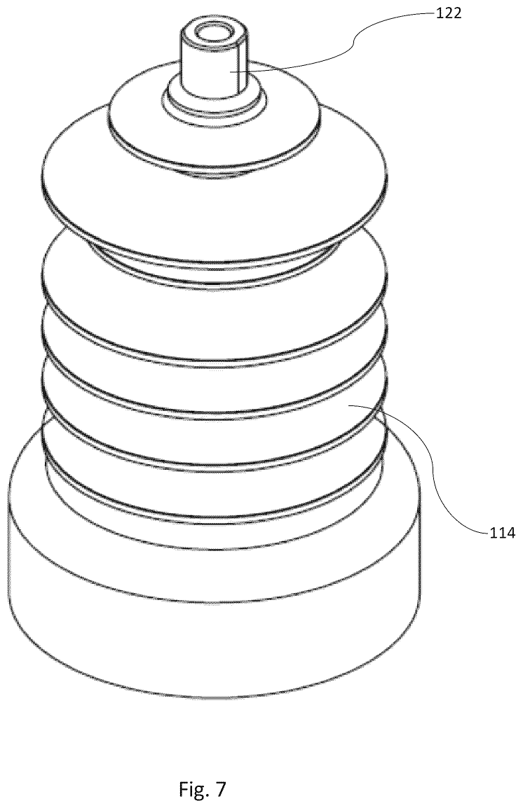

The following paragraphs describe the present disclosure with reference to FIGS. 1 to 10. In the figures, the same element or elements which have similar functions are indicated by the same reference signs. For promoting an understanding of the principles of the disclosure, reference will now be made to specific embodiments illustrated in the drawings and specific language will be used to describe the same. It will nevertheless be understood that no limitation of the scope of the invention is thereby intended, such alterations and further modifications in the illustrated methods, and such further applications of the principles of the invention as illustrated therein being contemplated as would normally occur to one skilled in the art to which the disclosure pertains.

Reference is made to FIGS. 1-4, which illustrate a modular pole assembly 100 [herein after referred to as the pole assembly]. The pole assembly 100 may include a top insulator housing 102 and a bottom insulator housing 104. The top insulator housing 102 may be defined by at least a wall which may further define a hollow space. The top insulator housing 102 includes a first end 116 and a second end 168. The top insulator housing 102 may also be defined with an inner surface 102i and an outer surface 1020. The first end 116 may be a top end of the top insulator housing 102 and the second end 168 may be a bottom end of the top insulator housing 102. The first end 116 of the top insulator housing 102 may be defined by an opening. The opening may be defined at the first end 116 along a substantially central section of the first end 116. The opening may be configured to removably accommodate the first terminal 118. The first terminal 118 may be configured in such a manner that a portion of the top insulator housing 102 may extend into a hollow space defined by the top insulator housing 102. Further, the second end 168 of the top insulator housing 102 may be defined as an open end. A region of the second end 168 may be defined by a first threaded section 172.

Particularly, the outer surface 1020 at the second end 168 of the top insulator housing 102 may be defined with the first threaded section 172. In this preferable and non-limiting embodiment, the first threaded section 172 may be defined along the outer surface 1020 of the top insulator housing 102 such that, the first threaded section 172 may extend parallel to a first axis (A-A′) of the pole assembly 100. Further, the second end 168 may also include a bottom surface 146 that extends in a direction that is perpendicular to the first threaded section 172 and the first axis (A-A′) of the pole assembly 100. The bottom surface 146 may be configured above the first threaded section 172 and may also be defined along the outer surface 1020 of the top insulator housing 102. The bottom surface 146 of the top insulator housing 102 may be defined with a semi-circular cutout [not shown in figures]. The semi-circular cutout may be configured to extend along the circumference or periphery of the bottom surface 146 and the top insulator housing 102. Further, the hollow space of the top insulator housing 102 may accommodate an interrupter 108 in an illustrated embodiment. The interrupter 108 may be housed in the hollow space such that, the interrupter 108 abuts the inner surface 102i of the top insulator housing 102. The interrupter 108 housed in the top insulator housing 102 may partially extend beyond the second end 168.

One end of the first terminal 118 may be connected to a power source and may be configured to receive electricity and the opposite end of the first terminal 118 may be conductively connected to a top end of the interrupter 108. The interrupter 108 in this non-limiting embodiment may be configured with a fixed conductor [not shown] and a movable conductor 108m. The movable conductor 108m may be selectively traversed to engage and disengage with the fixed conductor. The interrupter 108 may be configured to transmit the electricity from the first terminal 118 when the movable conductor 108m is in contact with the fixed conductor. This condition may herein be termed as an engaged condition of the interrupter 108. Further, the transfer of electricity is terminated when the movable conductor 108m is traversed away from the fixed conductor and the same is termed as a disengaged condition of the interrupter 108. In this non-limiting embodiment, the movable conductor 108m is accommodated along a bottom region of the interrupter 108 and the movable conductor 108m may extend into the bottom insulator housing 104.

The bottom insulator housing 104 may also be defined by a wall which defines a hollow space. The bottom insulator housing 104 may be defined with a third end 166 and a fourth end 152. The bottom insulator housing 104 may also be defined with an inner surface 104i and an outer surface 1040. The third end 166 may be a top end of the bottom insulator housing 104 and the fourth end 152 may be a bottom end of the bottom insulator housing 104. The fourth end 152 of the bottom insulator housing 104 may be enclosed and the third end 166 of the bottom insulator housing 104 may be defined as an open end. The fourth end 152 of the bottom insulator housing 104 may include a second sealing ring 150. The second scaling ring 150 may extend between the inner surfaces 104i of the bottom insulator housing 104. The second sealing ring 150 may prevent moisture and other dust particles from seeping into the hollow region of the bottom insulator housing 104.

A region of the third end 166 may be defined by a second threaded section 174. Particularly, the outer surface 1040 at the third end 166 of the bottom insulator housing 104 may be defined with the second threaded section 174. In this preferable and non-limiting embodiment, the second threaded section 174 may be defined along the outer surface 1040 of the bottom insulator housing 104 such that, the second threaded section 174 extends parallel to the first axis (A-A′) of the pole assembly 100. Further, the third end 166 may also include a top surface 148 that extends in a direction that is perpendicular to the second threaded section 174 and the first axis (A-A′) of the pole assembly 100. The top surface 148 may be configured above the second threaded section 174 and may also be defined along the inner surface 104i of the bottom insulator housing 104. The top surface 148 of the bottom insulator housing 104 may be defined with a semi-circular cutout [not shown in figures]. The semi-circular cutout may be configured to extend along the circumference or periphery of the top surface 148 and the bottom insulator housing 104.

The top insulator housing 102 and the bottom insulator housing 104 may be removably coupled to each other. The top insulator housing 102 and the bottom insulator housing 104 in this preferable and non-limiting embodiment may be coupled to each other through the first threaded section 172 and the second threaded section 174. The first threaded section 172 and the second threaded section 174 may be defined with threads that engage with each other. The top insulator housing 102 may initially be positioned within the bottom insulator housing 104. Further, one of the top insulator housing 102 and the bottom insulator housing 104 may be rotated with respect to the other. The first threaded section 172 engages with the second threaded section 174 and secures the top insulator housing 102 to the bottom insulator housing 104. Further, the bottom surface 146 and the top surface 148 are oriented such that the semi-circular cut out of the bottom surface 146 and the top surface 148, together define a second groove 144. The second groove 144 may extend between the second end 168 and the third end 166 of the top insulator housing 102 and the bottom insulator housing 104, respectively. The second groove 144 may be configured to accommodate a first sealing ring 142. The first sealing ring 142 may facilitate an airtight coupling between the top insulator housing 102 and the bottom insulator housing 104. The above configuration at the second end 168 and the third end 166 enables the first sealing ring 142 to be accommodated in a manner which prevents moisture from seeping into the hollow regions of the top insulator housing 102 and the bottom insulator housing 104. The above configuration at the second end 168 and the third end 166 with the first threaded section 172 and the second threaded section 174 respectively, may also enable an easier removal and coupling of the top insulator housing 102 and the bottom insulator housing 104. In a preferable and non-limiting embodiment, the top insulator housing 102 and the bottom insulator housing 104 are made of material including but not limited to thermoclastic material. In a preferable and non-limiting embodiment, the interrupter 108 may be any device which is operable for selectively conducting electricity, including but not limited to vacuum interrupter. In an embodiment, the top insulator housing 102 and the bottom insulator housing 104 may be coupled to each other through means including but not limited to threads, snap fit arrangement etc.

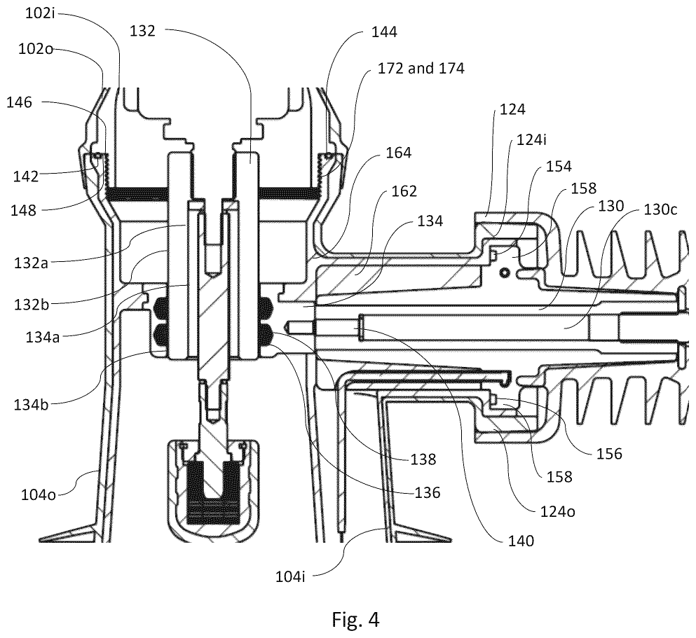

The hollow space defined by the walls of the top insulator housing 102 and the bottom insulator housing 104 may accommodate a first conductor 132 and a second conductor 134. The first conductor 132 may be a hollow elongated structure and the first conductor 132 may be conductively coupled to a bottom end of the interrupter 108. Particularly, the first conductor 132 may be conductively coupled to the movable conductor 108m of the interrupter 108. The bottom end of the movable conductor 108m of the interrupter 108 may be accommodated inside the hollow region of the first conductor 132. The movable conductor 108m may abut an inner surface 132a of the first conductor 132 and the movable conductor 108m may be fixedly coupled to the first conductor 132. The first conductor 132 may be oriented to lie along the first axis (A-A′). Particularly, the first conductor 132 may be oriented such that the hollow section of the first conductor 132 extends through the first axis (A-A′) of the pole assembly 100. The first conductor 132 may be configured to move with the movable conductor of the interrupter 108. The hollow space defined by the walls of the bottom insulator housing 104 may also accommodate an actuator 170. One end of the actuator 170 may be accommodated on the fourth end 152 of the bottom insulator housing 104 and the opposite end of the actuator 170 may be conductively coupled to a bottom end of the interrupter 108. As seen from FIG. 4, one end of the actuator 170 may extend into the hollow region of the first conductor 132 and the actuator 170 may be fixedly coupled to the movable conductor of the interrupter 108. The actuator 170 may be selectively operated to impart a vertical movement to the first conductor 132 and the movable conductor of the interrupter 108. Thus, the first conductor 132 is traversable along the first axis (A-A′) of the pole assembly 100. The actuator 170 in a non-limiting embodiment may be operated by any known means including but not limited to an electric motor, a hydraulic means etc. In an embodiment of the disclosure, the hollow space in the top insulator housing 102 and the bottom insulator housing 104 may accommodate components including but not limited to the interrupter 108 and the actuator 170.

The pole assembly 100 may also include a second conductor 134. The second conductor 134 may also be a hollow elongated structure that is defined in a shape including but not limited to that of a tubular structure. The second conductor 134 may be defined by an inner surface 134a and an outer surface 134b. The inner surface 134a of the second conductor 134 may be defined with at least one first groove 138 [hereinafter referred to as the first groove]. The first groove 138 may extend throughout the circumference or periphery along inner surface 134a of the second conductor 134. The first groove 138 may be defined to extend along a plane that is perpendicular to the first axis (A-A′). In this preferable embodiment, at least two first grooves 138 may be defined along the inner surface 134a of the second conductor 134. Both the first grooves 138 may be defined along planes that are parallel to each other. Further, the planes of both the first grooves 138 that are parallel to each other may also be oriented perpendicular to the first axis (A-A′) of the pole assembly 200.

The pole assembly 100 may also include at least one conductor plug 136 [hereinafter referred to as the conductor plug]. The conductor plug 136 may be positioned within the first groove 138. In this preferable embodiment, the conductor plug 136 may be in the shape of a ring and the conductor plug 136 may be configured to abut the inner surface 132a of the first conductor 132. In this preferable and exemplary embodiment, the conductor plug 136 and the second conductor 134 may be of electrically conductive material. The diameter of the second conductor 134 measured from the second conductor 134 to the inner surface 134a of the second conductor 134 may be equivalent to slightly greater than the diameter of the first conductor 132 that is measured from the center of the first conductor 132 to the inner surface of the first conductor 132. The first conductor 132 and the second conductor 134 may be coupled to each other such that the inner surface 134a of the second conductor 134 abuts the outer surface 132b of the first conductor 132. Further, the second conductor 134 may be fixedly connected to the bottom insulator housing 104 and the outer surface 134b of the second conductor 134 may abut the inner surface 104i of the bottom insulator housing 104. As the actuator 170 is operated, the first conductor 132 may traverse vertically along the first axis (A-A′) and the second conductor 134 may remain fixed. The outer surface 132b of the first conductor 132 abuts the conductor plug 136 positioned in the first groove 138 of the second conductor 134. The conductor plug 136 that in structured as the spring enables the conduction of high voltages and the above configuration also hinders/reduces the risk of electrical breakdown during conduction of electricity from the first conductor 132 to the second conductor 134.

The pole assembly 100 may also include a chamber 106 that extends perpendicularly from at least one of the second end 168 of the top insulator housing 102 and the third end 166 of the bottom insulator housing 104. The chamber 106 may be defined by walls that extend from at least one of the top insulator housing 102 and the bottom insulator housing 104. The chamber 106 may also be defined with an outer surface 1060. In this preferable and non-limiting embodiment, the chamber 106 may be configured to extend from the bottom insulator housing 104. The chamber 106 may be configured to extend along a second axis (A-A′) which is perpendicular to the first axis (A-A′) of the pole assembly 100. Further, the chamber 106 may be configured to extend from the region of the bottom insulator housing 104 that lies proximal or adjacent to the second conductor 134 in the bottom insulator housing 104. The chamber 106 may further be defined by a proximal end 164 and a distal end 126. The proximal end 164 of the chamber 106 may be the region that extends from the bottom insulator housing 104. Further, a flange 124 may extend from the distal end 126 of the chamber 106. The flange 124 may extend outwardly from the chamber 106 and the flange 124 may be defined with a diameter that is greater than the diameter of the walls defining the chamber 106. The flange 124 may further be defined by an inner surface 124i and an outer surface 1240.

The pole assembly 100 further includes at least one sensor 128 [hereinafter referred to as the sensor]. The sensor 128 may be configured to measure the voltage in the pole assembly 100. Reference is made from FIG. 4 to FIG. 6. The sensor 128 may include an extension 158 that extends from the surface of the sensor 128. The extension 158 may be a plate-like structure that is housed or fixedly accommodated substantially on a central region of the sensor 128. The extension 158 may be defined with a third groove 156. The third groove 156 may be a cut out that extends along the circumference of the extension 158. The sensor 128 may include a third conductor 130. The third conductor 130 may be a hollow tubular shaped structure defined with a second cavity 130c. The second cavity 130c may be hole that extends though out the length of the sensor 128. Further, a bushing 162 is housed within the chamber 106 and the bushing 162 is positioned adjacent to the proximal end 164 of the chamber 106. The bushing 162 may also be defined with a central hole that extends throughout the length of the bushing 162. The shape of the bushing 162 may be defined such that an outer surface of the bushing 162 abuts an inner surface of the chamber 106. Further, the hole extending throughout the center of the bushing 162 may define an inner surface which complements the shape of the sensor 128. For instance, the hole in the bushing 162 may be defined with a semi conical shape which complements that semi conical shape of the sensor 128. The sensor 128 may be accommodated within the bushing 162 such that the outer surface of the sensor 128 abuts the inner surface of the bushing 162.

The sensor 128 is accommodated in the chamber 106 such that the second cavity 130c of the third conductor 130 extends along the second axis (B-B) of the pole assembly. Further, the sensor 128 is accommodated in the bushing 162 such that one end of the third conductor 130 abuts the second conductor 134 in the bottom insulator housing 104. The third conductor 130 of the sensor 128 may be coupled to the second conductor 134 such that the electricity from the second conductor 134 is conducted to the third conductor 130. Further, region of the second conductor 134 that lies adjacent to the third conductor 130 and along the second axis (B-B) may be defined with a threaded hole. The threaded hole may be defined in the second conductor 134 such that the threaded hole is an extension of the second cavity 130c in the third conductor 130. Further, a fastener 140 may be inserted into the second cavity 130c and the same may be engaged by threads with the threaded hole in the second conductor 134. Thus, the sensor 128 may be secured with the second conductor 134 through the fastener 140. The above configuration of coupling the sensor 128 with the second conductor 134 through the fastener 140 and the threaded hole must not be considered as a limitation and other configurations including but not limited to snap fit arrangements may be used. Further, the extension 158 of the sensor 128 may be positioned to abut or lie adjacent to the flange 124 of the chamber 106. The extension 158 of the sensor 128 may be configured to abut the inner surface 124i of the flange 124 such that the third groove 156 lies adjacent to the inner surface 124i of the flange 124. The third groove 156 may further accommodate a third sealing ring 154 and the third sealing ring 154 is structured to abut an inner surface 160 of the flange 124. The above configuration at the third groove 156 in the extension 158 enables the third sealing ring 154 to be accommodated in a manner which prevents moisture from seeping into the chamber 106.

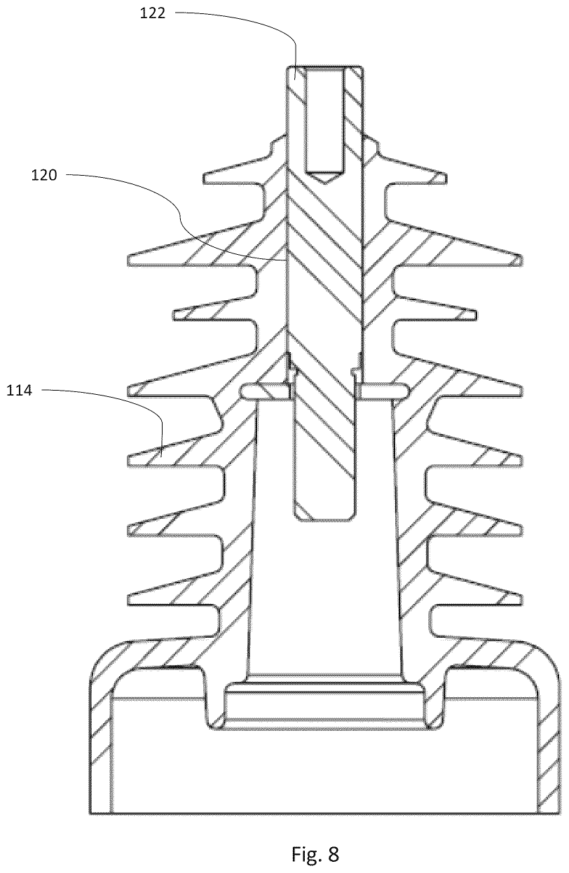

Reference is made to FIG. 7 and FIG. 8 which illustrate a silicon jacket 114 for the chamber 106. The silicon jacket 114 may be configured or provided on the outer surface 1060 of the chamber 106. The silicon jacket 114 may be provided to close the first cavity 106a of the chamber 106. The silicon jacket 114 may be defined with a central cavity for accommodating a second terminal 122. The second terminal 122 may partially protrude out from the silicon jacket 114. Further, this silicon jacket 114 may be configured to enclose the chamber 106 and the sensor 128 accommodated in the chamber 106. At least a portion of the silicon jacket 114 abuts the outer surface 1240 of the flange 124 at the distal end 126 of the chamber 106. The silicon jacket 114 may be removably coupled to the flange 124 such that the region of the silicon jacket 114 that sits on the outer surface 1240 of the flange 124 is slidable over the outer surface 1240 of the flange 124. Further, the second terminal 122 in the silicon jacket 114 may be configured to be accommodated within the second cavity 130c of the third conductor 130 when the silicon jacket 114 is assembled to enclose the chamber 106. The second terminal 122 may be configured to receive electricity from the third conductor 130. The above configuration of the sensor 128 with the removable silicon jacket 114 enables an easy replacement of the sensor 128 when damaged. The silicon jacket 114 may be initially removed and the fastener 140 may be removed for disconnecting and replacing the sensor 128 from the second conductor 134. Consequently, the cost of repairing the pole assembly 100 is significantly reduced as the sensor 128 may be individually replaced from the pole assembly 100. The top insulator housing 102 and the bottom insulator housing 104 may also be configured with silicon jackets 110, 112. The silicon jackets 110, 112 may be configured in a removable manner to the top insulator housing 102 and the bottom insulator housing 104. The above configuration of the pole assembly 100 with the silicon jackets 110, 112 and 114 may be for one of live tank overhead line system including but not limited to a live tank circuit breaker, a live tank auto recloser, a live tank vacuum switch disconnector.

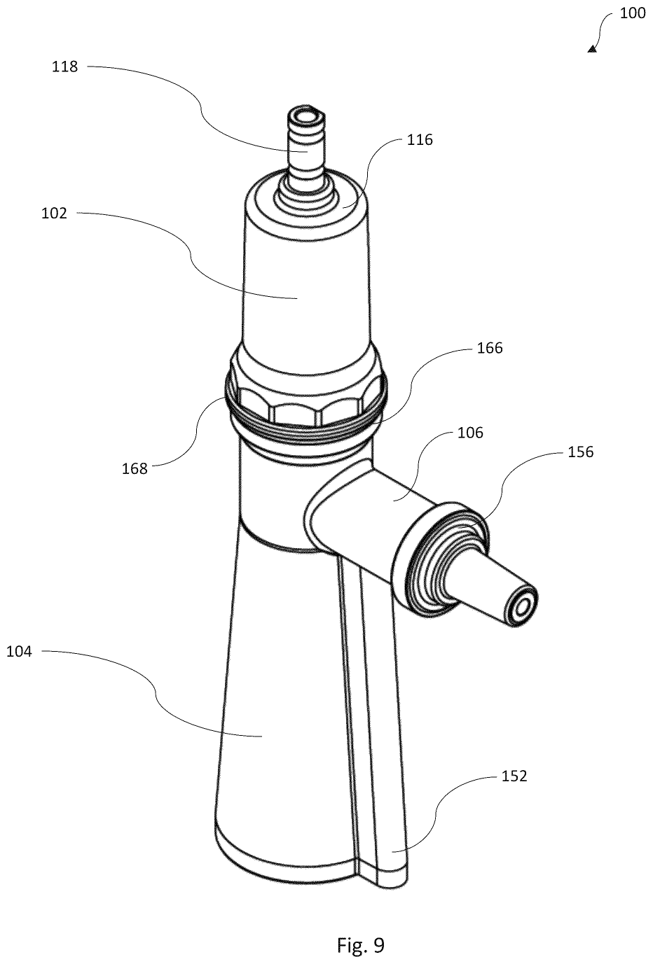

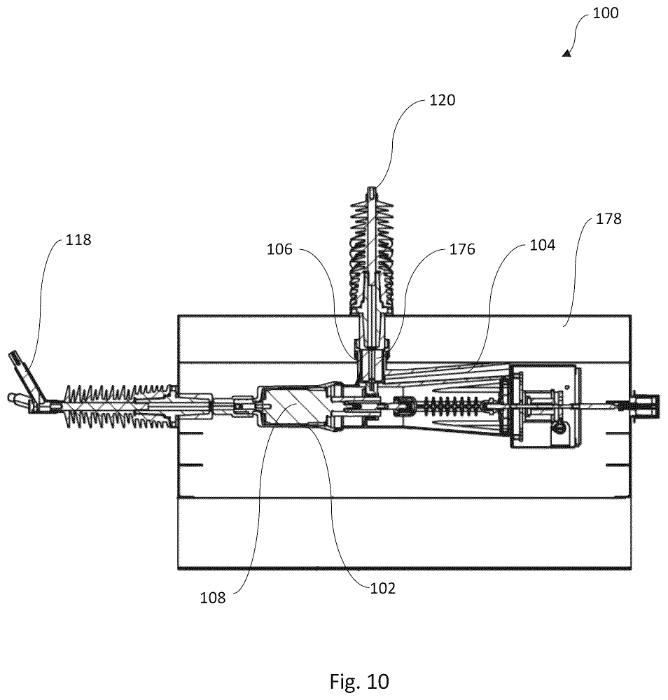

Reference is further made to FIG. 9 and FIG. 10 that illustrate a dead tank. The pole assembly 100 without the silicon jacket 110, 112, 114 may be for one of dead tank overhead line system including but not limited to a dead tank circuit breaker, a dead tank auto recloser, a dead tank vacuum switch disconnector. As seen from FIG. 10, the pole assembly 100 may be accommodated in an insulated casing 178. The configuration of the pole assembly 100 in the dead tank may be similar to the configuration of the pole assembly 100 in the live tank. Further, the chamber 106 may be configured to accommodate an adapter 176. The adapter 176 may be a conductive element that is positioned to abut the second conductor 134 in the chamber 106. The sensor 128 may further be positioned adjacent to the adapter 176 in the chamber 106. Therefore, the sensor 128 and the silicon jacket 114 protrude out of the casing 178 and accessible externally. Consequently, the sensor 128 may be externally replaced without dismantling the casing 178 or accessing the pole assembly 100 in the casing 178.

In an embodiment, an arcing distance between the first terminal 118 and the second terminal 122 may be varied. The silicon jacket 114 on the chamber 106 may be partially moved along the second axis (B-B) and over the flange 124 such that the distance between the first terminal 118 and the second terminal 122 is varied. Thus, the arcing distance between first terminal 118 and the second terminal 122 may be suitably varied.

In an embodiment, the modular pole assembly 100 with the silicon jacket 110, 112, 114 accommodated on the top insulator housing 102, the bottom insulator housing 104 and the chamber 106, forms the live tank. The silicon jacket 110, 112, 114 may be effortlessly removed from the top insulator housing 102, the bottom insulator housing 104 and the chamber 106 of the modular pole assembly 100. The modular pole assembly 100 may be subsequently adapted or positioned in the casing 178 as seen from the FIG. 10 which forms the dead tank. Thus, the modular pole assembly 100 is adaptable to form the live tank or the dead tank by selectively removing or accommodating the silicon jacket 110, 112, 114. Consequently, manufacturing costs for live tank and dead tank reduces and modular pole assembly 100 is easily adaptable to form the live tank or the dead tank. In an embodiment, the sensor 128 may also be easily replaced by removing the silicon jacket 114 on the chamber 106. The modular pole assembly 100 is configured such that the sensor 128 is easily accessible by removing the silicon jacket 114 on the chamber 106. Thus, a faulty or damaged sensor 128 may be individually replaced without having to replace the complete modular pole assembly 100.

In an embodiment of the disclosure, an interrupter is disposed in the top insulator housing and extends into the bottom insulator housing.

In an embodiment of the disclosure, at least one silicon jacket is coupled to an outer surface of each of the top insulator housing, the bottom insulator housing and the chamber.

In an embodiment of the disclosure, the chamber is defined with a flange at a distal end of the chamber, and the flange is structured to support a portion of the at least one sensor.

In an embodiment of the disclosure, at least a portion of the at least one silicon jacket abuts an outer surface of the flange at the distal end of the chamber.

In an embodiment of the disclosure, a first conductor is conductively coupled to the interrupter.

In an embodiment of the disclosure, a second conductor conductively coupled to the first conductor wherein, an inner surface i of the second conductor is defined with at least one first groove.

In an embodiment of the disclosure, a conductor plug is accommodated in the at least one first groove, and the conductor plug is structured to an outer surface b of the first conductor.

In an embodiment of the disclosure, the at least one sensor is removably coupled by a fastener, extending through a provision along a length of the at least one sensor and coupled with the second conductor.

In an embodiment of the disclosure, a first sealing ring accommodated in a second groove defined on a bottom surface of the top insulator housing and a top surface of the bottom insulator housing.

In an embodiment of the disclosure, a second sealing ring disposed to the fourth end of the bottom insulator housing.

In an embodiment of the disclosure, a third sealing ring disposed in a third groove defined on an extension of the at least one sensor wherein, the third sealing ring is structured to abut an inner surface of the flange.

In an embodiment of the disclosure, the modular pole assembly is of a thermoplastic material.

In an embodiment of the disclosure, a bushing is positioned at a proximal end in the chamber and accommodating the at least one sensor.

In an embodiment of the disclosure, the at least one silicon jacket is configured to close the first cavity as defined by the third chamber.

In an embodiment of the disclosure, the modular pole assembly with at least one silicon jacket forms a live tank and the modular pole assembly housed in a casing without the at least one silicon jacket defines a dead tank.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Referral numerals:

| Detailed description | Referral numeral |
|---|---|
| Modular pole assembly | 100 |
| Top insulator housing | 102 |
| Bottom insulator housing | 104 |
| Chamber | 106 |
| First cavity | 106a |
| Outer surface | 106o |
| Interrupter | 108 |
| Movable conductor | 108m |
| Silicon jacket | 110 |
| Silicon jacket | 112 |
| Silicon jacket | 114 |
| First end | 116 |
| First terminal | 118 |
| Outer surface of the second terminal | 120 |
| Second terminal | 122 |
| Flange | 124 |
| Outer surface of the flange | 124o |
| Inner surface of the flange | 124i |
| Distal end | 126 |
| Sensor | 128 |
| Third conductor | 130 |
| Second cavity | 130c |
| First conductor | 132 |
| Inner surface of the first conductor | 132a |
| Outer surface of the first conductor | 132b |
| Second conductor | 134 |
| Inner surface of the second conductor | 134a |
| Inner surface of the second conductor | 134b |
| Conductor plug | 136 |
| First groove | 138 |
| Fastener | 140 |
| First sealing ring | 142 |
| Second groove | 144 |
| Bottom surface of the top insulator housing | 146 |
| Top surface of the bottom insulator housing | 148 |
| Second sealing ring | 150 |
| Fourth end | 152 |
| Third sealing ring | 154 |
| Third groove | 156 |
| Extension | 158 |
| Bushing | 162 |
| Proximal end | 164 |
| Third end | 166 |
| Second end | 168 |
| Actuator | 170 |
| First threaded section | 172 |
| Second threaded section | 174 |
| Adapter | 176 |
| Casing | 178 |
| Pole assembly | 100 |

What is claimed is:

1. A modular pole assembly for overhead line systems, comprising:
a top insulator housing having a first end and a second end;
a bottom insulator housing having a third end and a fourth end, wherein the third end is removably coupled to the second end; and
at least one wall extending perpendicularly from at least one of the second end of the top insulator housing and the third end of the bottom insulator housing, the at least one wall defining a chamber structured to accommodate at least one sensor.

2. The modular pole assembly of claim 1, further comprising an interrupter disposed in the top insulator housing and extending into the bottom insulator housing.

3. The modular pole assembly of claim 1, further comprising at least one silicon jacket coupled to an outer surface of each of the top insulator housing, the bottom insulator housing, and the chamber.

4. The modular pole assembly of claim 3, wherein the chamber is further defined by a flange disposed at a distal end of the chamber, the flange being structured to support a portion of the at least one sensor.

5. The modular pole assembly of claim 4, wherein at least a portion of the at least one silicon jacket abuts an outer surface of the flange at the distal end of the chamber.

6. The modular pole assembly of claim 2, further comprising a first conductor conductively coupled to the interrupter.

7. The modular pole assembly of claim 6, further comprising a second conductor conductively coupled to the first conductor, wherein an inner surface of the second conductor is defined with at least one first groove.

8. The modular pole assembly of claim 7, further comprising a conductor plug accommodated in the at least one first groove, wherein the conductor plug is structured to an outer surface of the first conductor.

9. The modular pole assembly of claim 7, wherein the at least one sensor is removably coupled by a fastener extending through a provision along a length of the at least one sensor and coupled with the second conductor.

10. The modular pole assembly of claim 1, further comprising a first sealing ring accommodated in a second groove defined on a bottom surface of the top insulator housing and a top surface of the bottom insulator housing.

11. The modular pole assembly of claim 1, further comprising a second sealing ring disposed on the fourth end of the bottom insulator housing.

12. The modular pole assembly of claim 4, further comprising a third sealing ring disposed in a third groove defined on an extension of the at least one sensor, wherein the third sealing ring is structured to abut an inner surface of the flange.

13. The modular pole assembly of claim 1, wherein at least a portion of the top and/or bottom insulator housing is made of a thermoplastic material.

14. The modular pole assembly of claim 1, further comprising a bushing positioned at a proximal end in the chamber and accommodating the at least one sensor.

15. The modular pole assembly of claim 1, wherein the at least one silicon jacket is configured to close the cavity.

16. The modular pole assembly of claim 1, wherein the at least one silicon jacket forms a live tank.

17. The modular pole assembly of claim 1, further comprising a casing that defines a dead tank.
